(19) United States
(12) Patent Application Publication
(10) Pub. No.: US 2025/0054842 A1
(43) Pub. Date: Feb. 13, 2025

(54) PACKAGE WITH CONCAVE WETTABILITY AND/OR METALLIZATION LAYER

(71) Applicant: Infineon Technologies AG, Neubiberg (DE)

(72) Inventors: Rowel TABAJONDA, Villach (AT); Michael STADLER, München (DE); Aira Lourdes Baring VILLAMOR, Melaka (MY); Mei Yih GOH, Durian Tunggal (MY); Juliane JUNESCH, Regensburg (DE); Chee Voon TAN, Seremban (MY); Mei Qi TAY, Malim (MY)

(73) Assignee: Infineon Technologies AG, Neubiberg (DE)

(21) Appl. No.: 18/792,118

(22) Filed: Aug. 1, 2024

(30) Foreign Application Priority Data
Aug. 8, 2023 (DE) 10 2023 121 111.0
Jul. 23, 2024 (DE) 10 2024 120 935.6

(51) Int. Cl. H01L 23/495; H01L 23/00

(52) U.S. Cl. CPC H01L 23/49548; H01L 23/49575; H01L 23/49582; H01L 24/32; H01L 23/49562; H01L 2224/32245; H01L 2924/35

(57) ABSTRACT

A package including a component for a package is disclosed. In one example, wherein the component comprises a functional body, and a wettability layer arranged on a main surface of the functional body and configured for promoting wetting of a connection medium to be applied on the wettability layer for connecting the component with a further component of the package. The wettability layer has a lateral circumference at least part of which having a concave edge.

### CROSS-REFERENCE TO RELATED APPLICATION

This Utility Patent Application claims priority to German Patent Application No. 10 2023 121 111.0, filed Aug. 8, 2023 and German Patent Application No. 10 2024 120 935.6, filed Jul. 23, 2024, which are both incorporated herein by reference.

### BACKGROUND

### Technical Field

Various embodiments relate generally to a component for a package, a package, and a method of manufacturing a package.

### Description of the Related Art

A conventional package may comprise an electronic component mounted on a chip carrier such as a leadframe, may be electrically connected by a bond wire extending from the chip to the chip carrier or to a lead, and may be optionally molded using a mold compound as an encapsulant.

In conventional packages, a rectangular wettability layer on a leadframe structure for carrying a semiconductor chip may define a region in which a solder material used for connecting leadframe structure and semiconductor chip can be formed. However, undesired phenomena such as bleed-out of solder at chip edges and/or incomplete chip corner coverage by solder may occur. Thus, reliability of a conventional package may be an issue due to inaccurate soldering or adhering during chip assembly.

### SUMMARY

There may be a need for a package with high reliability.

According to an exemplary embodiment, a component for a package is provided, wherein the component comprises a functional body, and a wettability layer arranged on a main surface of the functional body and configured for promoting wetting of a connection medium to be applied on the wettability layer for connecting the component with a further component of the package, wherein the wettability layer has a lateral circumference at least part of which having a concave edge.

According to another exemplary embodiment, a package is provided which comprises a component having the above-mentioned features, a further component, and a connection medium, wherein the further component is connected with the component by the connection medium on the wettability layer.

According to an exemplary embodiment, a method of manufacturing a package is provided, wherein the method comprises arranging a wettability layer on a main surface of a functional body of a component for promoting wetting of a connection medium to be applied on the wettability layer, forming the wettability layer with a lateral circumference at least part of which having a concave edge, applying the connection medium on the wettability layer, and connecting the component with a further component by the connection medium.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a three-dimensional view of a package according to an exemplary embodiment.

FIG. 2 illustrates a plan view of a conventional package according to a simulation.

FIG. 3 illustrates a plan view of a package according to a simulation of an exemplary embodiment.

FIG. 4 illustrates an image of a conventional package.

FIG. 5 illustrates an image of a package according to an exemplary embodiment.

FIG. 6 illustrates a plan view of a component for a package according to an exemplary embodiment.

FIG. 7 illustrates a plan view of a component for a package according to another exemplary embodiment.

FIG. 8 illustrates a plan view of a package according to still another exemplary embodiment.

FIG. 9 illustrates a cross-sectional view of a package according to yet another exemplary embodiment.

FIG. 10 illustrates different views of constituents of a package according to an exemplary embodiment.

FIG. 11 illustrates a plan view of a package formed by the constituents of FIG. 10.

FIG. 12 illustrates a three-dimensional view of a detail of a component for a package according to FIG. 10 and FIG. 11.

FIG. 13 illustrates simulation results concerning solder coverage of the package of FIG. 11.

FIG. 14 illustrates plan views of a package with different conventionally occurring assembly issues.

FIG. 15 illustrates plan views of a package according to an exemplary embodiment in which assembly issues are overcome by an auto align function of features of exemplary embodiments.

FIG. 16 illustrates simulation results concerning solder coverage of the package of FIG. 15.

### DETAILED DESCRIPTION

There may be a need for a package with high reliability.

According to an exemplary embodiment, a component for a package is provided, wherein the component comprises a functional body, and a wettability layer arranged on a main surface of the functional body and configured for promoting wetting of a connection medium to be applied on the wettability layer for connecting the component with a further component of the package, wherein the wettability layer has a lateral circumference at least part of which having a concave edge.

According to another exemplary embodiment, a package is provided which comprises a component having the above-mentioned features, a further component, and a connection medium, wherein the further component is connected with the component by the connection medium on the wettability layer.

According to an exemplary embodiment, a method of manufacturing a package is provided, wherein the method comprises arranging a wettability layer on a main surface of a functional body of a component for promoting wetting of a connection medium to be applied on the wettability layer, forming the wettability layer with a lateral circumference at least part of which having a concave edge, applying the connection medium on the wettability layer, and connecting the component with a further component by the connection medium.

According to still another exemplary embodiment, a package is provided which comprises a carrier, a semiconductor chip having an electrically conductive connection layer, and a connection medium connecting the electrically conductive connection layer with the carrier, wherein the electrically conductive connection layer has a lateral circumference at least part of which having a concave edge.

According to an exemplary embodiment, a package manufacturing architecture may be provided in which a component (for example a leadframe structure) and a further component (for instance a semiconductor chip) are connected by a connection medium (for example solder or assembly adhesive) attached onto a wettability layer of the component. Descriptively speaking, the wettability layer shall define a region within which connection medium can be provided and remains, whereas substantially no connection medium shall remain outside of or around the wettability layer. Advantageously, the wettability layer may be formed with a lateral circumference at least part of which having a concave edge. It has been surprisingly found that, by an at least partially concave edge or edge portion along at least part of a perimeter of a wettability layer promoting wetting by the connection medium, beneficial and well-defined target properties of the obtained component-component connection may be achieved. More specifically, by shaping the edge of the wettability layer in a concave fashion, unintentional bleed-out of connection medium at component edges may be reliably prevented. Furthermore, a concave edge may improve component corner coverage by connection medium. These benefits have been confirmed both by simulations and by experiments. Consequently, a correspondingly manufactured package may show excellent mechanical and electric reliability. For example, the concave shape can be a stepped profile or a smooth (or continuously curved) profile. Additionally or alternatively, a metallization layer of a semiconductor chip may have a concave shape.

### Description of Further Exemplary Embodiments

In the following, further exemplary embodiments of the component, the package, and the method will be explained.

In the context of the present application, the term “package” may particularly denote an electronic device which may comprise one or more electronic components mounted on a (in particular electrically conductive) carrier. Said constituents of the package may be optionally encapsulated at least partially by an encapsulant. Optionally, one or more electrically conductive interconnect bodies (such as metallic pillars, bumps, bond wires and/or clips) may be implemented in a package, for instance for electrically coupling and/or mechanically supporting the electronic component.

In the context of the present application, the term “component” may particularly denote any member, constituent or element of a package, in for example of a chip package. For instance, said component (and/or said further component) may be a chip carrier such as a leadframe structure, an electrically conductive connection element such as a clip, and/or an electronic component such as a semiconductor die.

In an embodiment, the component is configured as one of a leadframe structure (or another carrier for an electronic component, such as a semiconductor chip), a clip, and an electronic component, for example a semiconductor chip.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by an encapsulant, together with the electronic component.

In the context of the present application, the term “leadframe” may particularly denote a sheet-like metallic structure which can be bent, punched and/or patterned so as to form leadframe bodies as mounting sections for mounting chips, and connection leads for electric connection of the package to an electronic environment. In an embodiment, the leadframe may be a metal plate (in particular made of copper) which may be patterned, for instance by stamping or etching. Forming a chip carrier as a leadframe is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “clip” may particularly denote a three-dimensionally curved connection element which comprises an electrically conductive material such as copper and is an integral body with sections to be connected to chip terminals and/or a chip carrier and/or leads.

In the context of the present application, the term “functional body” may particularly denote a physical structure of a component providing at least part of a target functionality of the component. For example, when the component is a leadframe structure, the functional body may be a die pad of the leadframe structure for accommodating an electronic component like a semiconductor die or chip. When a component is a clip, the functional body may be a patterned and/or curved electrically conductive plate having a coupling interface for coupling an electronic component such as a semiconductor die. In an embodiment in which the component is an electronic component such as a semiconductor chip, the functional body may be a semiconductor substrate with monolithically integrated circuit element(s) in an active region and metallic connection structures (such as pads or terminals) thereon. The functional body of a component may be configured for connection with a further component.

In the context of the present application, the term “wettability layer” may particularly denote a, for example flat or planar, film, sheet or plate having a surface property promoting wetting by a (for example flowable during processing) connection medium (such as solder or adhesive) thereon. In particular, wetting may denote the ability of a connection medium to maintain contact with a solid surface of the wettability layer, in particular resulting from intermolecular interactions when the two are brought together. The degree of wetting may be denoted as wettability and may be determined by a force balance between adhesive and cohesive forces.

In the context of the present application, the term “connection medium” may particularly denote a material which may be configured for, preferably mechanically and electrically, connecting a component with a further component. Such a connection medium may be flowable during processing, and may be rendered (in particular permanently) solid by hardening, curing or the like. Examples for a connection medium are a solder, a glue or an assembly adhesive, or even a sinterable or semi-sinterable material.

In the context of the present application, the term “lateral circumference of the wettability layer” may particularly denote a closed perimeter of the wettability layer between two opposing main surfaces of the wettability layer. Hence, the lateral circumference of the wettability layer may relate to a thin sidewall of the wettability layer rather than to is larger top and bottom main surfaces. Preferably, the entire lateral circumference of the wettability layer may lie in a common plane.

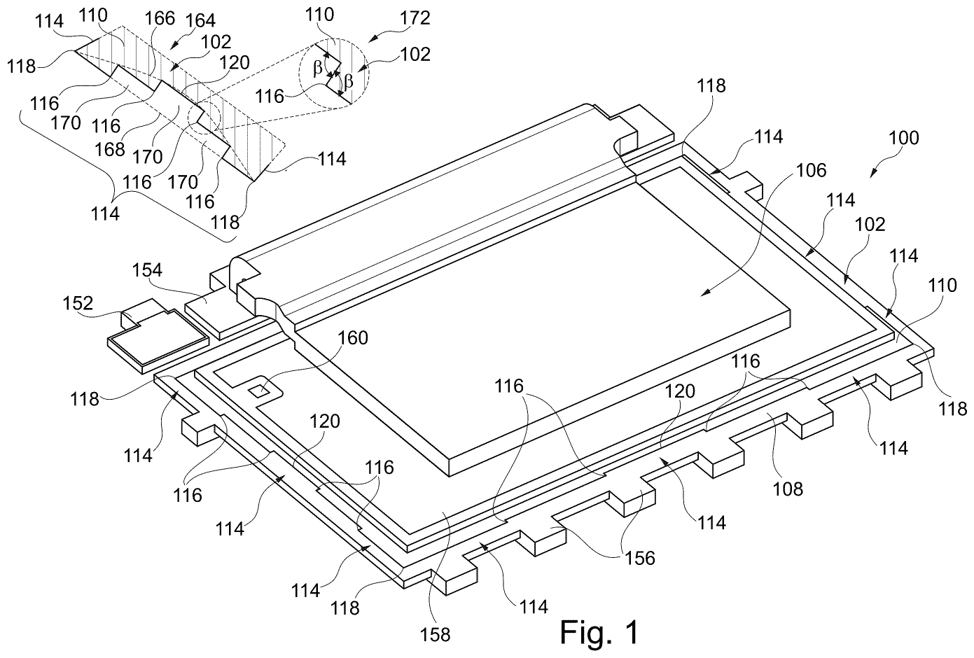

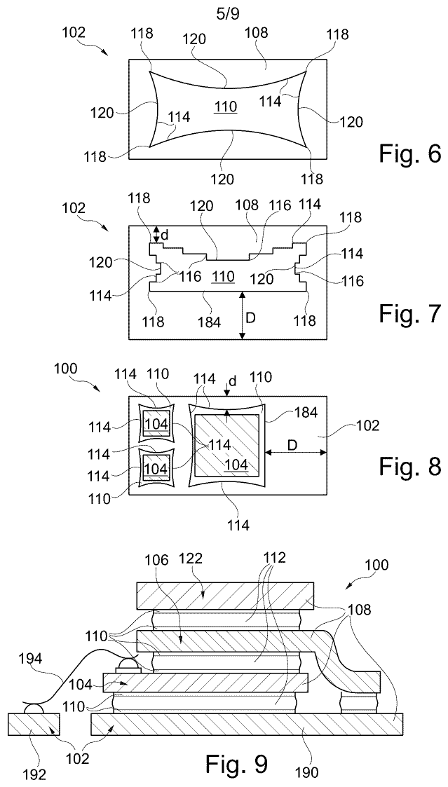

In the context of the present application, the term “at least partially concave edge of the wettability layer” may particularly denote at least part of a circumference (for instance one side edge or a section of one side edge or the entire circumferential side edge) of the edge of the wettability layer having an outline that curves inwards at least in a section. In particular, concave may mean bending inwardly, for example bending inwardly towards a center of the wettability layer. Hence, the at least partially concave edge of the wettability layer may create at least one indentation or recess in an edge region between two adjacent corners. Such an inwardly curving outline or outline portion of the edge may be defined by a continuously curved or smooth outline section (see for instance FIG. 6), or by an outline section being delimited by a stepped sequence of outline section parts (see for instance FIG. 1 or FIG. 7). Also combinations between continuously curved, stepped and/or straight outline sections along an exterior circumference of the wettability layer are possible in other embodiments.

In the context of the present application, the term “main surface” of a body may particularly denote a largest body surface of one of the largest body surfaces. For instance, a body (such as a clip or a carrier or a chip or a wettability layer or part thereof) may be plate-shaped or substantially plate-shaped and may then have two opposing main surfaces separated by body material in a thickness direction and connected with each other by a circumferential edge.

In an embodiment, the wettability layer is a plating layer. A plating layer may be a layer formed at least partially by plating, for example by depositing a metal on a surface (for instance by electroless plating or sputtering). It is possible to do concave plating directly on components, such as a leadframe, a clip or a chip. A sputtering mask may be used in said process to define the partially or entirely concave circumference of the wettability layer, since such a mask can be provided with any desired shape.

In an embodiment, the plating layer comprises or consists of silver, when the component is configured as a leadframe structure or as a clip. Silver may have excellent wetting properties, so that a solder may be distributed homogeneously over a silver surface of the plating layer, rather than separating or splitting up into several separate islands of solder on a wettability layer. Advantageously, silver plating may provide a better wetting than other materials (such as copper). Thus, the silver material may control the bleeding properties positively. In particular, it has been found that silver plating can help to contain solder under the chip, i.e. to suppress bleed-out of solder. Silver material and other types may be used particularly preferably on a leadframe (in particular for a die pad) or a clip.

In an embodiment, the plating layer comprises or consists of one of the group comprising palladium, gold, titanium, nickel, and NiNiP, when the component is configured as an electronic component, for example a semiconductor chip. The mentioned materials show very good wetting properties on a semiconductor chip. Hence, an appropriate plating material on a chip may be palladium, gold, titan or others.

Although the plating materials mentioned in the previous paragraphs may be preferred choices, the plating material can be any material with affinity to an implemented connection medium (in particular a solder). For example, silicon does not have this affinity (i.e. solder cannot wet silicon properly). Therefore, in order to make silicon wettable, the plating may be done. On the die pad, a primary purpose of the plating may be to guide the spreading and/or distribution of the solder.

In an embodiment, the wettability layer has the concave edge along its entire lateral circumference. This may ensure excellent properties in terms of bleeding prevention and proper corner coverage with connection medium over the entire extension of the wettability layer.

However, it may also be possible that only part of the circumferential edge of the wettability layer is concave, and another part of the circumferential wettability layer is non-concave (for example comprises one or more straight and/or convex edge sections). For instance, a concave edge may be formed where a clearance distance of a further component (such as a semiconductor chip) on a component (such as a leadframe structure) is small. If there is a region of a large clearance resistance, the concavity of the edge may be locally omitted in such a region. For instance when a small clearance distance is present everywhere around the further component, the wettability layer can have a concave edge along each of four sides of its substantially rectangular lateral circumference.

In an embodiment, the concave edge is a stepped concave edge with a plurality of steps. For example, when connecting (for instance inner or outer) step corners with each other by a virtual curved line, said line may be concave (see reference sign 166 in FIG. 1). Advantageously, a stepped profile may be beneficial to control the so-called Marangoni effect when applied to the behavior of a connection medium on a wettability layer. The Marangoni effect relates to the concentration dependence of surface tension. The Marangoni effect may denote a mass transfer along an interface between two phases due to a gradient of the surface tension. To put it shortly, since surface tension depends on concentration, a stepped concave edge may lead to a particularly reliable prevention of excessive bleeding of connection medium (such as flowable solder) beyond the limits of the stepped concave edge. The mentioned steps of the concave edge may also have an impact on the local evaporation rate. More specifically, the evaporation rate may be locally higher where the steps are present, and may be locally lower between adjacent steps. This phenomenon may contribute to a proper meniscus geometry of connection medium on the wettability layer.

In an embodiment, the steps are defined by a step angle (see “β” in FIG. 1) in a range from 45° to 135°, for example in a range from 60° to 120°, more specifically in a range from 80° to 100°. Such a step angle may be present at outer and/or inner steps. Preferably, the step angle of the steps may be 90° or can be something around 90°. The mentioned angular ranges are particularly appropriate for adjusting desired properties of the wettability layer in view of the Marangoni effect.

In an embodiment, at least part of the concave edge is formed at one side of the lateral circumference between two corners, wherein the concavity leads to an innermost central edge portion between the two corners. Descriptively speaking, such a geometry of the wettability layer may pull the connection medium inwardly in an innermost central portion of the concave edge, whereas the connection medium may be pulled outwardly at or around corners between adjacent concave edges. Thus, the described geometry may promote at the same time improved component (for example chip) corner coverage as well as a strong suppression of bleed-out at component (for example chip) edges.

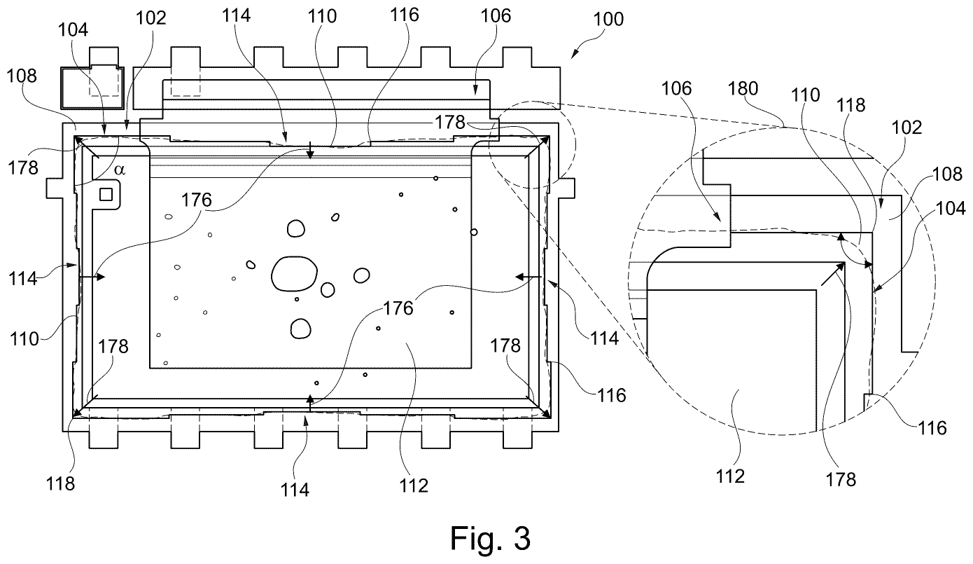

In one embodiment, a corner at an interface between two adjacent edges of the wettability layer may have an angle (which may be denoted as corner angle, see “α” in FIG. 3) in a range from 45° to 135°, for instance in a range from 60° to 120°, preferably of 90° or at least approximately 90°. In the mentioned angular ranges, an advantageous corner coverage by connection medium may be achieved.

In an embodiment, the concave edge has at least two steps, for example at least four or at least six steps, along said one side. As already mentioned, a stepped concave edge may be advantageous in particular in view of the Marangoni effect. The number of steps along one edge between two adjacent corners may be an even number for obtaining homogeneous properties in terms of bleed-suppression and corner coverage along the entire circumference. A number of steps per edge in a range from two to six, preferably an even number of steps per edge in said range, may be a highly appropriate tradeoff between simplicity and efficiency, in particular in view of the Marangoni effect.

In an embodiment, the connection medium comprises a solder. In the context of the present application, the term “solder” may be a solderable material which can be subjected to soldering to thereby establish an electrically conductive solder connection between component and further component. For instance, such a solder structure may be a film or layer of solder or may be a solder bump. For example, it is possible to use a solder paste with lead-based or bismuth-based solder materials. It may also be possible to use a solder structure comprising tin.

In an embodiment, the connection medium comprises an assembly adhesive. In one embodiment, the assembly adhesive may be a glue, for example an electrically conductive glue. It is also possible that such an assembly adhesive may be a die attach paste. The assembly adhesive may also be any resin-based assembly adhesive, including semi-sintering materials. What concerns hybrid and semi-sintering materials, a corresponding paste may be a partially adhesive and partially sintering paste, for example a silver filled adhesive. Thus, an assembly adhesive may be resin based, while pure sintering products may be solvent based. They can be handled with the same or similar processes as other die attach adhesives. Hence, all resin-based die attach or assembly materials can be used as the connection medium. For example, the assembly adhesive can be epoxy based, or based on acrylic, silicone, Bismaleimides (BMI) and/or hybrid materials.

In an embodiment, the component is a chip carrier, for instance a leadframe structure, and the further component is an electronic component, for example a semiconductor chip. When assembling a semiconductor chip on a chip carrier by soldering or using an assembly adhesive, a wettability layer with concave edges on the chip carrier may allow to assemble the semiconductor chip without excessive solder-bleeding and/or with rectangular corners showing appropriate solder coverage.

In another embodiment, the component is a clip (for example a bent and patterned metallic structure) and the further component is an electronic component, for example a semiconductor chip (for instance a power semiconductor chip). When assembling the semiconductor chip on the clip, or vice versa, by soldering or using an assembly adhesive, a wettability layer with concave edges on the clip and/or the chip may allow to establish a package with advantageous properties in terms of solder bleeding and corner coverage with solder material.

In an embodiment, the package comprises a third component (for example a carrier (such as a leadframe structure), a clip or an electronic component) and further connection medium (for instance further solder or further assembly adhesive), wherein the third component is connected with the further component by the further connection medium on a further wettability layer, which has a lateral circumference at least part of which having a concave edge (and which, more generally, can be embodied as the above-described wettability layer), of the further component and/or of the third component. To put it shortly, the package may be formed as a component stack comprising at least three stacked components, wherein the connection between each adjacent pair of components may be established using a concave wettability layer on one or both of the connected components.

Still referring to the previously described embodiment, the package comprises a fourth component (for example a carrier (such as a leadframe structure), a clip or an electronic component) and a third connection medium (for instance further solder or further assembly adhesive), wherein the fourth component is connected with the third component by the third connection medium on a third wettability layer, which has a lateral circumference at least part of which having a concave edge (and which, more generally, can be embodied as the above-described wettability layer), of the third component and/or of the fourth component. For example, the component may be a chip carrier, the further component may be a semiconductor chip, and the third component may be a clip. For instance, the fourth component may be a further semiconductor chip. Thus, sophisticated stacks of components may be created with a plurality of wettability layers having concave edges. An example is shown in FIG. 9 illustrating a stack of a leadframe-type carrier, a semiconductor chip thereon, a clip on said semiconductor chip, and a further semiconductor chip on top of the clip. Many other combinations of three, four, five or more stacked components are possible.

In an embodiment, the package is configured as power package. A power package may be a package comprising at least one power chip as electronic component. Thus, the package may be configured as power module, for instance molded power module such as a semiconductor power package. For instance, an exemplary embodiment of the package may be an intelligent power module (IPM). Another exemplary embodiment of the package is a dual inline package (DIP).

Correspondingly, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc.

In an embodiment, the package comprises an encapsulant encapsulating at least part of the components, for example of at least part of a carrier and at least part of an electronic component. In the context of the present application, the term “encapsulant” may particularly denote a substantially electrically insulating material surrounding at least part of an electronic component and at least part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In an embodiment, the package comprises an electrically conductive coupling element electrically coupling the component with the further component, for example an electronic component with a carrier and/or with at least one lead structure. Such an electrically conductive coupling clement may be a clip, a bond wire or a bond ribbon.

In an embodiment, at least one side of the lateral circumference of the wettability layer has a concave edge with at least two concave indentations in the respective side. It has been found that the formation of two, three or more concave indentations in one (for example straight) side of a (for instance substantially rectangular) wettability layer may lead to an advantageous pattern of solder formed on such a wettability layer. Moreover, forming multiple indentations with concave characteristics in such a wettability layer may allow to avoid solder formation in specific regions corresponding to the concave portions where no material of the wettability layer is present. For instance in a scenario in which specific surface regions shall be prevented from solder coverage, multiple concave portions may allow to achieve this objective. For instance, such indented regions may be those where active devices (for instance of a further component, such as a semiconductor chip, connected with the wettability layer and the functional body) are located which shall not be electrically connected to the solder material.

In an embodiment, the functional body has a lateral circumference at least part of which having a concave edge following a concave contour of the concave edge of the wettability layer. Advantageously, also the functional body itself and not only the wettability layer thereon may have concave properties along at least part of its circumference. At least in a concave section of the outline of the wettability layer, also the functional body may have a corresponding concave section following the shape of the concave section of the wettability layer.

Still referring to the previously described embodiment, the functional body (which may have a lateral circumference at least part of which having a concave edge following a concave contour of the concave edge of the wettability layer) comprises or consists of a die paddle. For instance, such a die paddle may be an electrically conductive chip carrier-such as a leadframe structure-or a portion thereof on which a further component-such as a semiconductor chip-may be mounted. This may allow to manufacture the functional body with low amount of material without compromising on its functionality. Furthermore, this may support the function of the concave edge of the wettability layer to maintain active devices or the like, for instance of a connected further component, free of electrically conductive material.

In an embodiment, the entire lateral circumference of the wettability layer is located inside the entire lateral circumference of the functional body so that an area of a main surface of the functional body is larger than an area of the wettability layer. In particular when the functional body substantially follows the contour of the wettability layer (for example at least in corresponding concave regions), a slightly bigger main surface area of the functional body compared with the wettability layer area may promote a better support of a connected further component, such as a semiconductor chip.

In an embodiment, the further component (for instance a semiconductor chip) has an exposed electrically conductive connection layer for connection with the wettability layer by the connection medium, said exposed electrically conductive connection layer (for instance a chip metallization, which may be a front side metallization and/or a back side metallization) having a lateral circumference at least part of which having a concave edge. Thus, an at least partially concave outline of the wettability layer may be present as well for the exposed electrically conductive connection layer of the further component. This may promote an auto alignment between functional body and further component during assembly.

In an embodiment, the concave edge of the exposed electrically conductive connection layer follows a contour of the concave edge of the wettability layer. In particular, the exposed electrically conductive connection layer facing the wettability layer with a connection medium in between may have one or more concave edge sections where the wettability layer has one more concave edge sections. Also this may promote an automatic alignment between functional body and further component when being assembled with connection medium in between.

In an embodiment, at least a portion of the concave edge of the exposed electrically conductive connection layer is laterally delimited by an electrically insulating and/or non-solderable delimitation structure of the further component. For example, such an electrically insulating and/or non-solderable delimitation structure may be arranged along part of or even along an entire circumference of the exposed electrically conductive connection layer. An example for said electrically insulating and/or non-solderable delimitation structure is an epoxy material. Descriptively speaking, such an electrically insulating and/or non-solderable delimitation structure may delimit or define a solderable area of the exposed electrically conductive connection layer.

In an embodiment, the delimitation structure covers a functionally active structure of the further component besides the exposed electrically conductive connection layer. Such a functionally active structure may for instance be an active region of a semiconductor chip-type further component which shall be covered with the electrically insulating and/or non-solderable delimitation structure and therefore can be decoupled from the connection medium, for instance a solder.

In an embodiment, the exposed electrically conductive connection layer is made of a solderable material. Such a solderable material can be a material capable of forming a partner structure in a solder connection, for instance a copper metallization layer.

In an embodiment, the further component is a semiconductor chip (such as a power semiconductor chip) and its exposed electrically conductive connection layer is a chip metallization layer (for instance a front side metallization and/or a back side metallization).

In an embodiment, the aforementioned semiconductor chip experiences a vertical current flow during operation of the package. For instance, the semiconductor chip may be a chip having both a front side metallization and a back side metallization for forming terminals or pads for establishing an electrical connection so that, during operation of the package, an electric current flows between the front side metallization at the back side metallization. For example, the semiconductor chip may be a transistor chip with source terminal, drain terminal and gate terminal, for instance having source terminal and drain terminal on opposing main surfaces of the semiconductor chip.

In an embodiment, the package is configured as one of the group consisting of a leadframe connected power module, a Control integrated power system (CIPOS) package, a Transistor Outline (TO) package, a Quad Flat No Leads Package (QFN) package, a Small Outline (SO) package, a Small Outline Transistor (SOT) package, and a Thin Small Outline Package (TSOP) package.

As substrate or wafer forming the basis of one or more electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

In conventional approaches, when soldering a large chip on a leadframe, there is the risk of bleed-out or solder overflow, i.e. a flow of solder into regions where solder is unwanted. In particular in the presence of large chips, an extensive overflow of solder into a clearance region of a package may occur. Moreover, chip corners and chip edges may show inadequate properties what concerns meniscus formation and bleed-out control. The described parasitic phenomena may also lead to further undesired effects, such as mold compound delamination.

According to exemplary embodiments, a component for a package and a package formed on the basis of such components are provided showing advantageous properties in terms of meniscus formation, bleed-out control as well as corner coverage. When connecting components (for instance a leadframe structure and a semiconductor chip) of a package, it may be possible to use a connection medium (such as solder or assembly adhesive) applied onto a surface of a wettability layer of at least one of the components. The wettability layer (also denoted as wetting layer) may be made of a material promoting wetting of the wettability layer by a connection medium. At the same time, spatial limits of the wettability layer shall define spatial limits beyond which the connection medium should not flow, at least not excessively. Beneficially, the wettability layer of a component and a package according to exemplary embodiments may comprise a lateral perimeter which may be at least partially concavely shaped. Advantageously, a concave edge of such a wettability layer may reliably prevent undesired bleeding of connection medium into unwanted regions and may enhance appropriate component corner coverage by connection medium during a connection process. Simulations and experiments show that the mentioned measures may provide a package with excellent reliability.

Descriptively speaking, a concave edge (which may be smoothly or continuously curved in a stepless way or, even more preferably, discontinuously stepped along an overall concave edge trajectory) may pull connection medium inwardly in particular in a retracted central edge portion between corners. Further advantageously, a corner defined between adjacent concave edges may pull connection medium outwardly into corner regions. Beneficially, this may lead to less bleeding of connection medium beyond edges while ensuring corner coverage with connection medium. The latter may prevent local overheating and burning due to corners being incompletely covered by connection medium.

More specifically, concave silver plating may be applied to a leadframe (as an example for the component) under a chip (as an example for the further component). Preferably but not necessarily, a concave edge shape of a wettability layer can be formed with a stepped profile. Advantageously, concave wettability layer formation (preferably by silver plating) may allow to achieve (1) a stable meniscus formation and (2) a reliable bleed out prevention, both at the chip corners and at the chip edges. In a preferred embodiment, concave wettability layer formation (for example by silver plating) may be executed to prevent solder bleed-out. For example, such an embodiment may be applied to solder-based die attachment, i.e. to an application in which the further component is a semiconductor chip. In particular, exemplary embodiments may allow soldering of a large chip to a leadframe without excessive solder bleeding while simultaneously ensuring appropriate corner coverage with solder-type connection medium.

As mentioned, a silver-plating wettability layer on a leadframe may possess a concave edge shape. Instead of a smooth concave curve (which may be possible in other embodiments), the silver plating may be preferably shaped as a stepwise concave profile. This serves three purposes: Firstly, this may promote complete chip corner wetting by controlling the bleed-out around the chip corners. Secondly, this may prevent bleed-out at the chip edges due to a change of wettability (since silver has a higher wettability than many other materials, such as copper). Thirdly, taking the mentioned measure may promote outgassing. Since the stepped profile is locally increasing the surface tension, an easier outgassing may be achieved.

Exemplary embodiments may be applied particularly advantageously for power packages with large chips (in particular having a surface area larger than 15 mm²) and/or having a small gap to the leadframe edges.

FIG. 1 illustrates a three-dimensional view of a package 100 according to an exemplary embodiment. For instance, package 100 according to FIG. 1 may be embodied as a semiconductor power package.

The illustrated package 100 comprises a component 102, which is here embodied as a leadframe structure. Said leadframe structure comprises a die pad 150 providing a mounting area for mounting a bare die thereon. The die pad 150 forms a functional body 108 of the component 102, since it provides the function of mounting the bare die thereon. Moreover, said leadframe structure may comprise one or a plurality of lead structures 152, 154 separate from the die pad 150 and each comprising one or more leads for contacting die terminals after encapsulating package 100. Also die pad 150 may comprise integrally formed leads 156. For example, the leadframe structure may be embodied as a patterned copper plate.

As shown, a wettability layer 110 (which may also be denoted as wetting layer) is arranged on an upper main surface of the functional body 108. Wettability layer 110 may be embodied as a patterned plated silver layer. The wettability layer 110 is configured for promoting wetting of a solder-type (or alternatively assembly-type) connection medium (not shown in FIG. 1, see reference sign 112 in FIG. 3). Such a connection medium 112 is to be applied on the wettability layer 110 for connecting the bottom-sided leadframe-type component 102 with a top-sided semiconductor chip-type further component 104 of the package 100.

As mentioned, the further component 104, which is here embodied as a power semiconductor transistor chip, form also part of package 100. In the shown example, the further component 104 is embodied as a field-effect transistor chip having a source pad 158, a drain pad (not shown) and a gate pad 160. As shown, the source pad 158 and the gate pad 160 are both arranged on the upper main surface of the further component 104. The drain pad is arranged on the lower main surface of the further component 104, and is therefore not visible in FIG. 1. The transistor chip is configured for a vertical current flow during operation.

The bottom main surface of the further component 104 is connected with the top main surface of the component 102 by the connection medium 112 on the wettability layer 110. Thereby, the drain pad becomes electrically accessible via the lead(s) 156. It is further possible to electrically couple the source pad 160 with the assigned lead structure 152, for example by a bond wire (not shown).

Apart from this, package 100 according to FIG. 1 comprises a third component 106, which is here embodied as a metallic clip. A bottom main surface of said third component 106 is connected with the source pad 158 at a top main surface of the further component 104 by further connection medium (not shown in FIG. 1, for example solder). This connection may be supported for example by providing a further wettability layer (not shown) on the bottom main surface of the third component 106. Since an end section of the further component 106 is connected on lead structure 154, the source pad 158 is electrically accessible from an outside of package 100 after encapsulation by lead structure 154.

Although not shown in FIG. 1, part of the component 102, the entire further component 104, the entire third component 106 and parts of the lead structures 152, 154 may be encapsulated by an encapsulant (not shown). After encapsulation, leads electrically coupled with the source pad 158, the drain pad and the gate pad 160 may be accessible from an exterior of the encapsulant for connection with an electronic periphery of package 100. For instance, said encapsulant may be a mold compound.

In order to obtain a package 100 with a high reliability, a specific design of the wettability layer 110 between components 102, 104 (and/or between components 104, 106) may be highly advantageous, as described in the following: As shown in FIG. 1 partially, the wettability layer 110 has a lateral circumference having an entirely concave edge 114. This design is illustrated completely for two edges 114 in FIG. 1 and partially for a third edge 114, but may be present at each of the four edges 114 of the wettability layer 110 on component 102 according to FIG. 1. Thus, the illustrated wettability layer 110 has a concave edge 114 along its entire lateral circumference. Furthermore, FIG. 1 shows a detail 164 which illustrates one edge 114 having a stepped concave design according to a preferred embodiment. More specifically, the shown wettability layer 110 has the concave edge 114 along each of its four sides of its substantially, but not completely rectangular lateral circumference, which has stepped concave indentations in each edge 114.

In the illustrated preferred embodiment, each concave edge 114 may be embodied as a stepped concave edge with a plurality of steps 116. Again referring to the detail 164, a virtual curved trajectory 166 connecting corners 118 between adjacent edges 114 and inner step corners defined by said steps 116 is illustrated in comparison with a hypothetic rectangular wettability layer outline 168. Moreover, the stepped concave edge 114 forms a stepped concave indentation 170 illustrated in the detail 164 of FIG. 1. Now referring to a further detail 172, the steps 116 are defined by inner and outer step angles, β, which may be in a range from 45° to 135°, and which assume a preferred value of 90° in the shown embodiment. The inner and the outer step angles may have identical or different angular values. Different inner step angles may have identical or different angular values. Different outer step angles may have identical or different angular values. The concave edge 114 shown in detail 164 is formed at one side of the lateral circumference between two corners 118 with adjacent edges 114. As illustrated, the concavity leads to an innermost central edge portion 120 between the two corners 118 forming an outermost edge region. In the shown embodiment, the concave edge 114 has four steps 116. Alternatively, any other—preferably even—number of steps 116 per edge 114 is possible, for instance two or six steps 116 at a respective edge 114.

The described design of the wettability layer(s) 110 with concavely stepped edges 114 has advantages: On the one hand, this may suppress unwanted bleeding of connection medium 112 into unwanted regions significantly beyond the limits of wettability layer 110. Furthermore, the described design of the wettability layer 110 may promote proper coverage of corners 118 with connection medium 112 during a connection process. Hence, the described edge design of wettability layer 110 may allow manufacture of a package 100 with a high mechanical and electrical reliability. The stepped concave silver plating applied to the leadframe-type component 102 of FIG. 1 may result in a stable meniscus formation. Moreover, a reliable bleed out prevention of connection medium 112 may be achieved in particular in the innermost central edge portions 120 of the edges 114. Hence, significant advantages may be achieved both at chip corners and at chip edges of the semiconductor chip illustrated as further component 104. The shown and described design may allow to reliably solder even a large chip to a leadframe. This may be achieved without excessive solder bleeding and with pronounced corner coverage with solder-type connection medium 112.

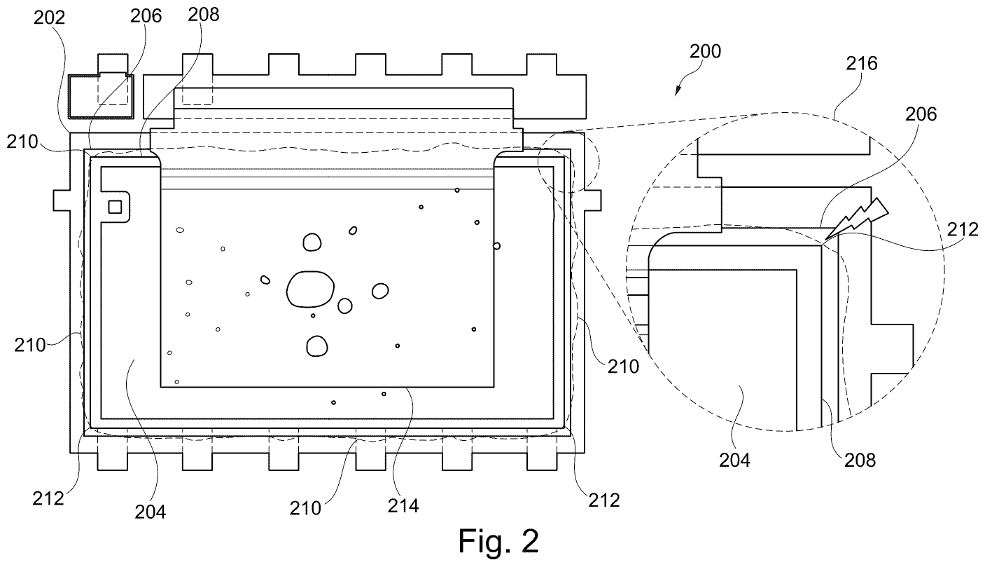

FIG. 2 illustrates a plan view of a conventional package 200 with connection medium 204 thereon according to a simulation.

To put it shortly, FIG. 2 shows a leadframe 202 covered with a rectangular wettability layer 206 on which solder-type connection medium 204 is applied for connecting a semiconductor chip 208 on top of leadframe 202. On top of semiconductor chip 208, a metallic clip 214 is attached.

More specifically, FIG. 2 shows a solder process simulation of package 200 with conventional rectangular plating. In certain areas, extensive solder overflow occurs, see reference signs 210. Hence, critical bleed-out of connection medium 204 may happen at the chip edges. As illustrated by reference signs 212 (see in particular detail 216), also incomplete chip corner coverage may occur.

FIG. 3 illustrates a plan view of a package 100 according to a simulation of an exemplary embodiment.

As indicated by arrows 176 in FIG. 3, the stepped concave edges 114 may pull connection medium 112 inwardly with a focus on a retracted central edge portion (see reference sign 120 in FIG. 1) between corners 118. Advantageously, this may efficiently suppress bleeding of connection medium 112 beyond the edges 114. Corners 118 between stepped concave edges 114, preferably having a corner angle, α, in a range from 80° to 100° (preferably) 90°, may pull connection medium 112 outwardly in regions adjacent to corners 118, see arrows 178 (in particular in detail 180). Thus, excessive heating resulting from corners 118 being incompletely covered by connection medium 112 may also be prevented, since the described corner design may lead to pronounced corner coverage with connection medium 112.

Thus, FIG. 3 shows a simulation result of a manufacture of package 100 according to an exemplary embodiment implementing concave stepped silver plating for forming wettability layer 110. More specifically, a solder process is simulated during which a solder-type connection medium 112 is applied to wettability layer 110 for connecting semiconductor die-type further component 104 on leadframe structure-type component 102. As shown in FIG. 3, improved chip corner coverage may be achieved. Furthermore, no excessive bleed-out occurs at the chip edges. Descriptively speaking, the wettability layer design has the effect of pulling back solder to prevent bleed out. In addition to the significantly reduced bleed-out, also a largely improved corner coverage may be achieved.

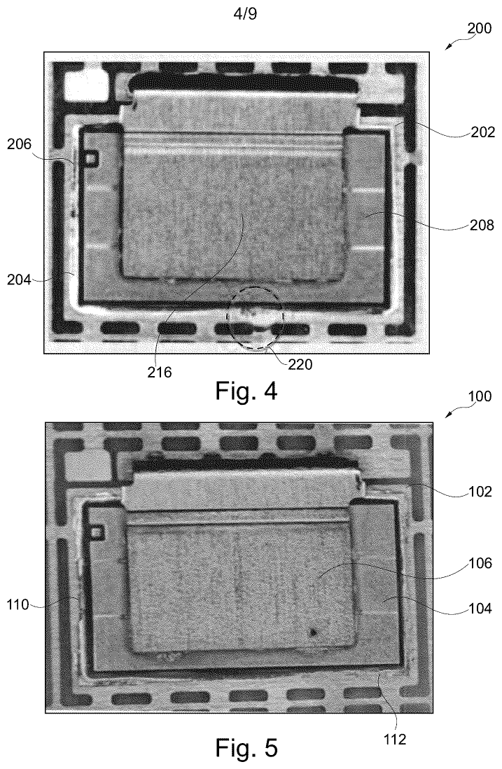

FIG. 4 illustrates an image of a manufactured conventional package 200.

The obtained package 200 is the result of an experimental test following a conventional manufacturing approach. In particular, a rectangular wettability layer 206 is formed on leadframe 202. As shown with reference sign 220, solder bleeding occurs after solder reflows following the contour of the plating shape of wettability layer 206.

FIG. 5 illustrates an image of a package 100 manufactured according to an exemplary embodiment.

The experimentally obtained package 100 according to FIG. 5 is based on the formation of a wettability layer 110 having a stepped concave circumferential edge 114 and being formed by silver plating. As shown, the silver-plating design with concave stepped edges 114 helps to reduce solder bleeding significantly in comparison with the conventional design according to FIG. 5.

FIG. 6 illustrates a plan view of a component 102 for a package 100 according to an exemplary embodiment.

The embodiment according to FIG. 6 differs from the embodiment of FIG. 1 in that, according to FIG. 6, the concave edge 114 extending along the entire circumference of the planar plated wettability layer 110 is completely smooth, stepless and continuous, with the exception of the four corners 118 between adjacent edges 114. Thus, the four concave edges 114 are free of steps 116.

While the embodiment of FIG. 1 has specific advantages concerning the Marangoni effect, the embodiment of FIG. 6 is simple in manufacture since it may be formed with a very simple plating mask.

FIG. 7 illustrates a plan view of a component 102 for a package 100 according to another exemplary embodiment.

The embodiment according to FIG. 7 differs from the embodiment of FIG. 1 in that, according to FIG. 7, only three concave edges 114 are formed along part of the circumference of the planar plated wettability layer 110. A fourth edge 184 delimiting wettability layer 110 is straight according to FIG. 7. Such a straight edge 184 may be sufficient when a clearance distance, D, between the respective edge 184 and an exterior edge of component 102 is sufficiently large. When a clearance distance, d<D, between a respective edge 114 and an exterior edge of component 102 is small, it may be advantageous to form the respective edge 114 with a stepped concave profile, as described above.

FIG. 8 illustrates a plan view of a package 100 according to still another exemplary embodiment.

In the embodiment of FIG. 8, the illustrated package 100 comprises a plurality of further components 104 (for instance a plurality of semiconductor chips of different sizes) attached on the same component 102, for instance on the same leadframe-type die pad. In regions in which the clearance distance is small (d), edges 114 of corresponding wettability layers 110 may be formed with a concave shape. In one or more other regions in which the clearance distance is large (D>d), one or more edges 184 of corresponding wettability layers 110 may be formed with a straight shape.

FIG. 9 illustrates a cross-sectional view of a package 100 according to yet another exemplary embodiment. To put it shortly, package 100 according to FIG. 9 relates to a stack of components 102, 104, 106, 122, wherein each two adjacent components 102, 104, 106, 122 may be connected by connection medium 112 and wettability layers 110 which may have a concave outline. The number of stacked components 102, 104, 106, 122 may be larger or smaller than four. The wettability layers 110 may be plated layers, for instance made of silver when formed on a leadframe-type component or made of palladium when formed on a chip-type component. For instance, the connection medium 112 may be metallic or alloy-type solder or resin-based assembly adhesive.

More specifically, package 100 according to FIG. 9 comprises a bottom-sided component 102 being covered with a wettability layer 110 and being configured as a leadframe structure comprising a die pad 190 and a lead structure 192.

A further component 104, which may be a semiconductor power chip, comprises a wettability layer 110 both on a bottom side as well as on a top side thereof. Further component 104 is connected with die pad 190 of component 102 by connection medium 112 in between which wets the connected wettability layers 110. Further component 104 may also be coupled with lead structure 192 by a bond wire 194.

A third component 106, which may be a metallic clip, may be connected with the further component 104 by further connection medium 112 on further concave wettability layers 110, as described above. The clip-type component 106 may also be directly connected with component 102, for instance also by soldering.

A fourth component 122, which may be a further semiconductor die, may be connected by additional connection medium 112 with the third component 106. For this purpose, third component 106 and/or fourth component 122 may be provided with concave wettability layers 110, as described above.

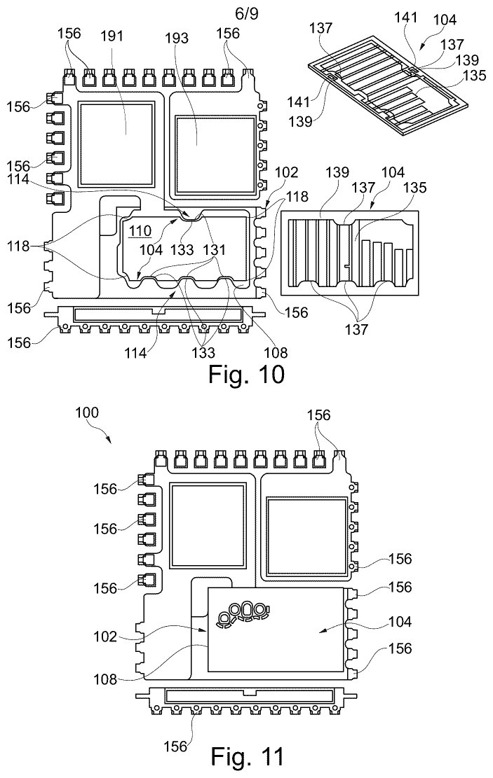

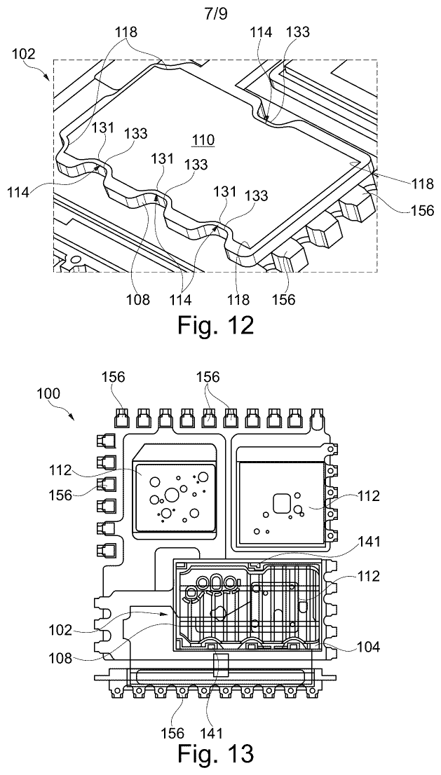

FIG. 10 illustrates different views of constituents of a package 100 according to an exemplary embodiment. FIG. 11 illustrates a plan view of a package 100 formed by the constituents of FIG. 10. FIG. 12 illustrates a three-dimensional view of a detail of a component 102 for a package 100 according to FIG. 10 and FIG. 11.

The illustrated package 100 comprises a patterned metal plate as leadframe structure constituting a component 102. Said leadframe structure comprises a die pad which forms a functional body 108 of the component 102 as it is designed for mounting a further component 104 in form of a semiconductor chip (which may be of a type experiencing a vertical current flow during operation of the package 100) thereon. The leadframe structure-type component 102 has connected or connectable leads 156 (which are only shown schematically and which may have any desired configuration). The further component 104 may co-work with other package sections 191, 193, such as further semiconductor chips or the like.

A wettability layer 110 is formed on an upper main surface of the functional body 108 and can be embodied as patterned silver plating layer. During a soldering process, the wettability layer 110 promotes wetting of a solder as a connection medium 112 (see FIG. 13). The connection medium 112 may be sandwiched between the wettability layer 110 and an exposed electrically conductive connection layer 135 of the semiconductor chip-type further component 104. The exposed electrically conductive connection layer 135 forms a metallization layer of the further component 104. In particular, the electrically conductive connection layer 135 may form a front side metallization of the semiconductor chip. For example, the exposed electrically conductive connection layer 135 may have an entire source pad on it, and the gate pad may be not visible because in SFET9 technology, there may be a routing inside the silicon chip so that the gate and sense pad may be re-located to the back side. More generally, the electrically conductive connection layer 135 should not be limited to a front side metallization or a back side metallization. The electrically conductive connection layer 135 may be on a side of the semiconductor chip-type further component 104 to be attached to the leadframe or carrier-type component 102.

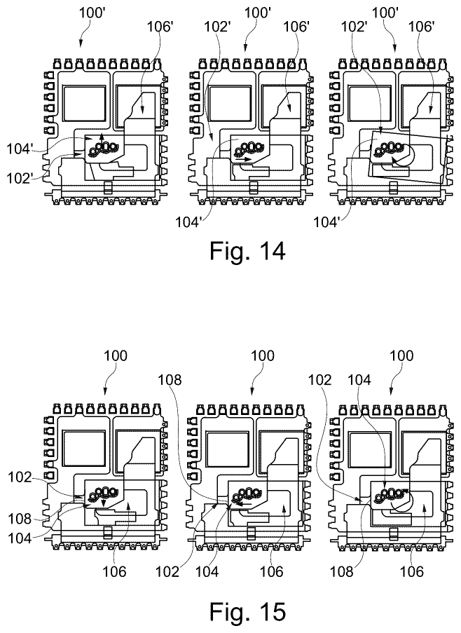

In addition, package 100 according to FIG. 11 may comprise a third component 106 such as a metallic clip (see FIG. 14 and FIG. 15). The third component 106 may electrically connect a further metallization layer of the further component 104 on a main surface facing away from the wettability layer 110 of the carrier-type component 102.

Although not shown in FIG. 1, part of the component 102, at least part of the further component 104, and at least part of the third component 106 as well as parts of the leads 156 may be encapsulated by an encapsulant, such as a mold compound (not shown).

According to FIG. 10 to FIG. 12, a lateral circumference has a concave edge 114 on two opposing sides of the wettability layer 110. One of said two opposing sides with concave edge(s) 114 has one concave indentation 131 and the other side has three concave indentations 131. In the shown example, the other two remaining sides of the substantially rectangular wettability layer 110 have no concave indentations 131, but are straight.

Moreover, optionally, also the die paddle-type functional body 108 on which the wettability layer 110 is formed may have a lateral circumference having a concave edge 133 following a concave contour of the concave edges 114 of the wettability layer 110.

For the sake of clarity, it should be said that the mentioned shape of the die pad is optional and may be omitted for further reducing the effort of manufacturing the die pad. In the latter mentioned scenario, it may be sufficient to have a silver plating layer in the described concave shape.

More specifically, a lateral circumference on two opposing sides of the functional body 108 may have a concave edge 133. One of said two opposing sides with concave edge(s) 133 has one concave indentation and the other side has three concave indentations. As shown, the entire lateral circumference of the wettability layer 110 is located inside the entire lateral circumference of the functional body 108. As a result, an area of a main surface of the functional body 108 is larger than an area of the wettability layer 110. This leads to a proper mechanical support for the chip-type further component 104.

As shown in FIG. 10 as well, the further component 104, embodied as semiconductor chip, has an exposed electrically conductive connection layer 135 as (for instance front side) metallization for connection with the wettability layer 110 by a connection medium 112, such as a solder. The electrically conductive connection layer 135 may refer to a metallization layer of the chip-type further component 104, which will be attached to the die pad-type component 102. Whether the electrically conductive connection layer 135 is made by a front side metallization process or by a back side metallization process may depend on the manufacturing process of the chip and how it is used, i.e. may depend on a desired application. Thus, the configuration of electrically conductive connection layer 135 as front side or back side metallization can be interchanged depending on the application requirements. In the illustrated embodiment, a flip chip attach is realized, but there can also be options to do a chip attach without flip chip. Said exposed electrically conductive connection layer 135 has a lateral circumference having a concave edge 137. According to FIG. 10, a lateral circumference on two opposing sides of the exposed electrically conductive connection layer 135 has concave edges 137. One of said two opposing sides with concave edge(s) 137 has one concave indentation and the other side has three concave indentations. In the shown example, the other two remaining sides of the exposed electrically conductive connection layer 135 have no concave indentations, but are straight. Thus, the concave edge 137 of the exposed electrically conductive connection layer 135 follows a contour of the concave edge 114 of the wettability layer 110. This may promote self-aligning between functional body 108 and further component 104 during assembly, see FIG. 14 and FIG. 15.

Furthermore, the concave edge 137 of the exposed electrically conductive connection layer 135 is laterally delimited by an electrically insulating and non-solderable delimitation structure 139 of the further component 104, which is here embodied as an epoxy material. For instance, said delimitation structure 139 may be arranged along an entire circumference, or only along part, of the exposed electrically conductive connection layer 135. Advantageously, the delimitation structure 139 covers functionally active structures 141 of the further component 104. These functionally active structures 141 may be electrically active devices of the further component 104 which shall not be brought in electrically conductive contact with the connection medium 112. The delimitation structure 139 electrically decouples the functionally active structures 141 from said connection medium 112.

The exposed electrically conductive connection layer 135 is made of a solderable material, such as copper. When connecting the functional body 108 with the further component 104 with solder-type connection medium 112 in between, the connection medium 112 connects the wettability layer 110 with the exposed electrically conductive connection layer 135, but not with the functionally active structures 141.

Summarizing, FIG. 10 to FIG. 12 show a package 100 which comprises a carrier and a semiconductor chip having an electrically conductive connection layer 135. A connection medium 112 may be provided for connecting the electrically conductive connection layer 135 with the carrier. The electrically conductive connection layer 135 may have a lateral circumference at least part of which having a concave edge 137. The package 100 may further comprise a wettability layer 110 arranged on a main surface of the carrier and configured for promoting wetting of the connection medium 112 to be applied on the wettability layer 110 for connecting the electrically conductive connection layer 135 of the semiconductor chip with the carrier. The wettability layer 110 may have a lateral circumference at least part of which having a concave edge 114. At least one side of the lateral circumference of the wettability layer 110 may have a concave edge 114 with at least two concave indentations 131 in the respective side. The concave edge 137 of the electrically conductive connection layer 135 may follow a contour of the concave edge 114 of the wettability layer 110. At least one side of the lateral circumference of the electrically conductive connection layer 135 may have a concave edge 137 with at least two concave indentations in the respective side. Thus, the package 100 may have a semiconductor chip inside, and the bottom side of the semiconductor chip may have the metallization 135 which has the special described shape. Thus, the package 100 may comprise a carrier, a semiconductor chip having the special described shape at the bottom side, and in between may be an adhesive layer or directly a solder layer. Moreover, a wettability layer having the above described features may be provided. Thus, a semiconductor package having the described special pattern metallization 135 on a bottom side may be provided.

Descriptively speaking, the embodiment of FIG. 10 to FIG. 12 provides irregular matching solderable structures (see reference signs 110, 135) for effective soldering. These features may be applied within the leadframe-type component 102 and within the semiconductor chip-type further component 104, specifically on the die pad and on the corresponding flipped low side chip.

The further component 104 may be an SFET-type field-effect transistor chip which has functionally active structures 141 on the top side that need to be covered with electrically insulating and non-solderable delimitation structure 139, such as epoxy resin, glue or blend. Consequently, the solderable opening is not regular rectangular or even square shaped, instead it is an irregular one in the shown embodiment. The illustrated design advantageously prevents the solder-type connection medium 112 from overlapping the epoxy covered active features for preventing reliability risks. At the same time, a proper support of the chip is provided to prevent chip crack.

The illustrated embodiment shows a design of the die paddle being such that its silver plating surface matches the pattern of the chip's front side solderable opening. The die paddle itself follows the contour of this silver plating surface but may be slightly bigger which also gives better support of the chip to avoid chip crack.

An advantageous aspect of the shown embodiment can be seen in the provision of two similar irregular solderable structures (see reference signs 110, 135) so that both can match together for effective soldering. The two structures are the silver plating surface on an island die paddle with similar contour, and the front side solderable area of the chip.

FIG. 10 to FIG. 12 show the assembly and the flip chip attach configuration of the low side field-effect transistor (LS-FET) and a corresponding effective coverage of the solder.

FIG. 13 illustrates simulation results concerning solder coverage of the package 100 of FIG. 11.

The simulation image shows an effective solder coverage as a result of the two similar outlines of wettability layer 110 and exposed electrically conductive connection layer 135.

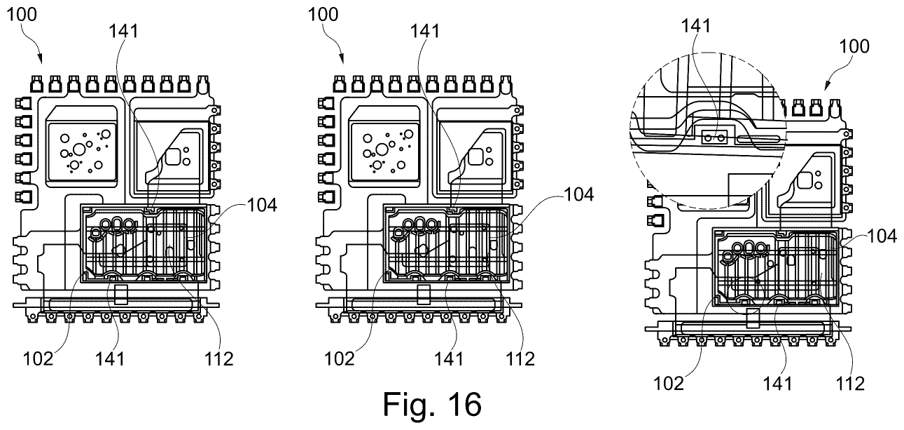

FIG. 14 illustrates plan views of a package 100′ (comprising a component 102′, a further component 104′ and a third component 106′) with different conventionally occurring assembly issues. FIG. 15 illustrates plan views of a package 100 according to an exemplary embodiment in which said assembly issues are overcome by an auto align function of features of exemplary embodiments. FIG. 16 illustrates simulation results concerning solder coverage of the package 100 of FIG. 15.

In addition to the epoxy of the chip, exemplary embodiments further secure active features (see reference sign 141 as described above) of the chip from any solder bridging and/or leakage risks.

The irregular shape of some features, as described above, also serves as an auto aligner of the chip.

At flip chip bonding, the chip may have an offset (FIG. 14 left hand side and middle) and/or rotation (FIG. 14 right hand side) from the machine's capability. During reflow, there may be a pulling effect of the silver plating and the front side metallization of the chip, thus reducing the offset. Consequently, the active features may be further protected. As shown in FIG. 15, undesired phenomena may be strongly suppressed by exemplary embodiments.

FIG. 16 shows that there is only at 5° rotation some risk that the active features overlap the solder. However, 5° rotation is already beyond a bond limit according to a specification.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A component for a package, wherein the component comprises:
a functional body; and
a wettability layer arranged on a main surface of the functional body and configured for promoting wetting of a connection medium to be applied on the wettability layer for connecting the component with a further component of the package;
wherein the wettability layer has a lateral circumference at least part of which having a concave edge.

2. The component according to claim 1, configured as one of a leadframe structure, a clip, and an electronic component, for example a semiconductor chip.

3. The component according to claim 1, wherein the wettability layer is a plating layer.

4. The component according to claim 3, comprising one of the following features:
wherein the plating layer comprises or consists of silver, when the component is configured as a leadframe structure or as a clip;
wherein the plating layer comprises or consists of one of the group comprising palladium, gold, titanium, nickel, and NiNiP, when the component is configured as an electronic component, for example a semiconductor chip.

5. The component according to claim 1, wherein the wettability layer has the concave edge along its entire lateral circumference.

6. The component according to claim 1, wherein the wettability layer has the concave edge along each of four sides of its substantially rectangular lateral circumference.

7. The component according to claim 1, wherein the concave edge is a stepped concave edge with a plurality of steps.

8. The component according to claim 7, wherein the steps are defined by a step angle (β) in a range from 45° to 135°, for example in a range from 60° to 120°, preferably in a range from 80° to 100°.

9. The component according to claim 1, wherein at least part of the concave edge is formed at one side of the lateral circumference between two corners, wherein the concavity leads to an innermost central edge portion between the two corners.

10. The component according to claim 9, wherein the concave edge has at least two steps, for example at least four or at least six steps, along said one side.

11. The component according to claim 1, wherein at least one side of the lateral circumference of the wettability layer has a concave edge with at least two concave indentations in the respective side.

12. The component according to claim 1, wherein the functional body has a lateral circumference at least part of which having a concave edge following a concave contour of the concave edge of the wettability layer.

13. The component according to claim 12, wherein the functional body comprises or consists of a die paddle.

14. The component according to claim 12, wherein the entire lateral circumference of the wettability layer is located inside the entire lateral circumference of the functional body so that an area of a main surface of the functional body is larger than an area of the wettability layer.

15. A package, wherein the package comprises:
a component according to claim 1;
a further component; and
a connection medium;
wherein the further component is connected with the component by the connection medium on the wettability layer.

16. The package according to claim 15, wherein the connection medium comprises a solder.

17. The package according to claim 15, wherein the connection medium comprises an assembly adhesive.

18. The package according to claim 15, wherein the component is a chip carrier, for instance a leadframe structure, and the further component is an electronic component, for example a semiconductor chip.

19. The package according to claim 15, wherein the component is a clip and the further component is an electronic component, for example a semiconductor chip.

20. The package according to claim 15, comprising a third component and further connection medium, wherein the third component is connected with the further component by the further connection medium on a further wettability layer, which has a lateral circumference at least part of which having a concave edge, of the further component and/or of the third component.

21. The package according to claim 20, comprising a fourth component and a third connection medium, wherein the fourth component is connected with the third component by the third connection medium on a third wettability layer, which has a lateral circumference at least part of which having a concave edge, of the third component and/or of the fourth component.

22. The package according to claim 20, wherein the component is a chip carrier, the further component is a semiconductor chip, and the third component is a clip.

23. The package according to claim 22, wherein the fourth component is a further semiconductor chip.

24. The package according to claim 15, wherein the further component has an exposed electrically conductive connection layer for connection with the wettability layer by the connection medium, said exposed electrically conductive connection layer having a lateral circumference at least part of which having a concave edge.

25. The package according to claim 24, wherein the concave edge of the exposed electrically conductive connection layer follows a contour of the concave edge of the wettability layer.

26. The package according to claim 24, wherein at least a portion of the concave edge of the exposed electrically conductive connection layer is laterally delimited by an electrically insulating and/or non-solderable delimitation structure of the further component.

27. The package according to claim 26, wherein the delimitation structure covers a functionally active structure of the further component besides the exposed electrically conductive connection layer.

28. The package according to claim 24, wherein the exposed electrically conductive connection layer is made of a solderable material.

29. The package according to claim 24, wherein the further component is a semiconductor chip and its exposed electrically conductive connection layer is a chip metallization layer.

30. The package according to claim 29, wherein the semiconductor chip experiences a vertical current flow during operation of the package.

31. The package according to claim 29, wherein the chip metallization layer is a front side metallization or a back side metallization.

32. A method of manufacturing a package, wherein the method comprises:
arranging a wettability layer on a main surface of a functional body of a component for promoting wetting of a connection medium to be applied on the wettability layer;
forming the wettability layer with a lateral circumference at least part of which having a concave edge;
applying the connection medium on the wettability layer; and
connecting the component with a further component by the connection medium.

33. A package which comprises:
a carrier;
a semiconductor chip having an electrically conductive connection layer; and
a connection medium connecting the electrically conductive connection layer with the carrier;
wherein the electrically conductive connection layer has a lateral circumference at least part of which having a concave edge.

34. The package according to claim 33,
comprising a wettability layer arranged on a main surface of the carrier and configured for promoting wetting of the connection medium to be applied on the wettability layer for connecting the electrically conductive connection layer of the semiconductor chip with the carrier;
wherein the wettability layer has a lateral circumference at least part of which having a concave edge.

35. The package according to claim 34, wherein at least one side of the lateral circumference of the wettability layer has a concave edge with at least two concave indentations in the respective side.

36. The package according to claim 34, wherein the concave edge of the electrically conductive connection layer follows a contour of the concave edge of the wettability layer.

37. The package according to claim 33, wherein at least one side of the lateral circumference of the electrically conductive connection layer has a concave edge with at least two concave indentations in the respective side.
